(19) United States
(12) Patent Application Publication
(10) Pub. No.: US 2014/0084318 A1
(43) Pub. Date: Mar. 27, 2014

(54) LIGHT EMITTING DEVICE PACKAGE AND PACKAGE SUBSTRATE

(71) Applicant: SAMSUNG ELECTRONICS CO., LTD., Suwon-si (KR)

(72) Inventor: Jung Hoon KIM, Hwaseong (KR)

(73) Assignee: SAMSUNG ELECTRONICS CO., LTD.

(21) Appl. No.: 13/922,587

(22) Filed: Jun. 20, 2013

(30) Foreign Application Priority Data
Sep. 27, 2012 (KR) 10-2012-0108340

(51) Int. Cl. H01L 33/62; H01L 33/60

(52) U.S. Cl. CPC H01L 33/62; H01L 33/60
USPC 257/98; 257/99; 257/79

(57) ABSTRACT

A light emitting device package is provide comprising a light emitting device including a first electrode and a second electrode. The package substrate allows the light emitting device to be mounted thereon and includes a first region and a second region electrically connected to the first electrode and the second electrode, respectively. At least one of the first region and the second region includes graphene.

### CROSS-REFERENCE TO RELATED APPLICATIONS

This application claims the priority of Korean Patent Application No. 10-2012-0108340 filed on Sep. 27, 2012, in the Korean Intellectual Property Office, the disclosure of which is incorporated herein by reference.

### TECHNICAL FIELD

The present disclosure relates to a light emitting device package and a package substrate.

### BACKGROUND

In general, a light emitting diode (LED) is widely used as a light source because it has various advantages including low power consumption and a high degree of luminance. Recently, light emitting devices have been employed as backlight units in illumination devices and in large liquid crystal displays. A light emitting device is provided as a package that can easily be installed in various devices such as an illumination device. As an amount of current injection is increased in a light emitting device package, heat dissipation performance in dissipating heat generated by a light emitting device becomes a critical factor. High heat dissipation performance is an important consideration in the field of high output light emitting device such as a backlight for a general illumination device where a large LED is required. Thus, research into a package substrate able to improve heat dissipation characteristics of a light emitting device without increasing unit cost in the production thereof has been actively conducted.

### SUMMARY

An aspect of the present disclosure provides a package substrate having excellent heat dissipation characteristics and improved electrical characteristics, and a light emitting device package including the same.

Another object of the present disclosure provides a package substrate that may be fabricated through a simple process and a thickness of which can be easily adjusted, and a light emitting device package including the same.

According to an aspect of the present disclosure, there is provided a light emitting device package including: a light emitting device including a first electrode and a second electrode; and a package substrate allowing the light emitting device to be mounted thereon and including a first region and a second region electrically connected to the first electrode and the second electrode, respectively, wherein at least one of the first region and the second region includes graphene.

In certain embodiments of the disclosure, the package substrate may include a first surface on which the light emitting device is mounted and a second surface opposing the first surface, and the graphene may extend from the first surface to the second surface in the first region and the second region.

In certain embodiments, at least one of the first region and the second region may have an area greater on the second surface than that on the first surface. At least one of the first region and the second region may be positioned below the light emitting device.

In certain embodiments, the package substrate may further include an insulating region positioned between the first region and the second region and electrically separating the first region and the second region. The first region and the second region may have a first thickness, and the insulating region may have a second thickness equal to or greater than the first thickness.

In certain embodiments, the insulating region may be made of a polymer resin.

In certain embodiments, the first electrode and the second electrode may be positioned on the same surface of the light emitting device, and the light emitting device may be mounted on the package substrate such that the first electrode and the second electrode face the first region and the second region, respectively. The entire surface of the first electrode may be connected to the graphene of the first region.

In certain embodiments, the first electrode and the second electrode may be positioned on different surfaces of the light emitting device, and the first electrode may be connected to the first region and the second region may be electrically connected to the second region by a conductive wire. The entire surface of the first electrode may be connected to the graphene of the first region.

In certain embodiments, the light emitting device package may further include: a phosphor layer provided on the light emitting device; and an encapsulator encapsulating the light emitting device.

In certain embodiments, the light emitting device package may further include a reflective layer provided on a lateral surface of the light emitting device.

In certain embodiments, a thickness of the package substrate may range from 20 μm to 200 μm.

According to another aspect of the present disclosure, there is provided a light emitting device package substrate including: at least one insulating region; and a plurality of conductive regions separated by the at least one insulating region and made of graphene. The plurality of conductive regions may extend from at least a portion of an upper surface on which a light emitting device is mounted, so as to be exposed to a lower surface thereof.

According to another aspect of the disclosure, a light emitting device package is provided comprising a substrate comprising an insulating region and a first and second conductive regions. A light emitting device overlies at least a portion of the first conductive region. A first electrode is in electrical contact with the light emitting device and the first conductive region. A second electrode is in electrical contact with the light emitting device and the second conductive region. The insulating and conductive regions extend from a first surface to a second opposing surface of the substrate. The first and second conductive regions are spaced apart from each other and the insulating region is located between the first and second conductive regions, and the first and second conductive regions comprise graphene.

In certain embodiments, the insulating region comprises a polymer resin.

In certain embodiments, the light emitting device comprises a plurality of layers laminated on the first surface of the substrate and the second electrode is disposed on the laminated layer that is at a furthest distance from the first surface of the substrate.

In certain embodiments, the light emitting device comprises a plurality of layers laminated on the first surface of the substrate and the second electrode is disposed on an intermediate layer that is not a layer that is at a furthest distance from the first surface of the substrate.

In certain embodiments, the light emitting device overlies the first and second conductive regions and the first and second electrodes are in direct electrical contact with the first and second conductive regions, respectively.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a cross-sectional view schematically illustrating a light emitting device package according to an embodiment of the present disclosure;

FIG. 2 is a cross-sectional view schematically illustrating a light emitting device package according to an embodiment of the present disclosure;

FIG. 3 is a cross-sectional view schematically illustrating a light emitting device package according to an embodiment of the present disclosure;

FIG. 4 is a cross-sectional view schematically illustrating a light emitting device package according to an embodiment of the present disclosure;

FIGS. 5A through 5I are cross-sectional views illustrating a sequential process of fabricating a light emitting device package according to an embodiment of the present disclosure;

FIG. 6 is a cross-sectional view schematically illustrating a light emitting device package according to an embodiment of the present disclosure;

FIG. 7 is a cross-sectional view schematically illustrating a light emitting device package according to an embodiment of the present disclosure;

FIG. 8 is a cross-sectional view schematically illustrating a light emitting device package according to an embodiment of the present disclosure;

FIG. 9 is a cross-sectional view schematically illustrating a light emitting device package according to an embodiment of the present disclosure;

FIG. 10 is a cross-sectional view schematically illustrating a light emitting device package according to an embodiment of the present disclosure;

FIG. 11 is a cross-sectional view schematically illustrating a light emitting device package according to an embodiment of the present disclosure;

FIG. 12 is a schematic cross-sectional view illustrating a backlight unit according to an embodiment of the present disclosure; and

FIG. 13 is a perspective view of a bulb-type lamp as an example of an illumination device according to an embodiment of the present disclosure.

### DETAILED DESCRIPTION

Embodiments of the present disclosure will now be described in detail with reference to the accompanying drawings.

The disclosure may, however, be embodied in many different forms and should not be construed as being limited to the embodiments set forth herein.

Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like components.

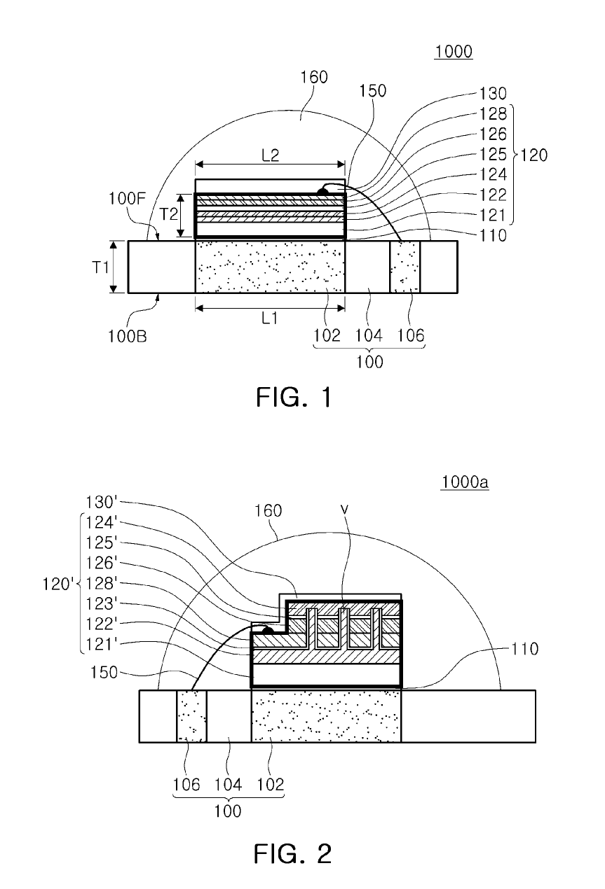

FIG. 1 is a cross-sectional view schematically illustrating a light emitting device package according to an embodiment of the present disclosure.

Referring to FIG. 1, a light emitting device package 1000 according to an embodiment of the present disclosure may include a package substrate 100, a light emitting device 120, a phosphor layer 130, and an encapsulator 160. The package substrate 100 may include a first region 102 and a second region 106 as conductive regions, and the first region 102 and the second region 106 may be electrically separated by an insulating region 104.

In certain embodiments, the first region 102 and the second region 106 may extend to have an overall thickness from an upper surface 100F to a lower surface 100B. Thus, the first region 102 and the second region 106 may be exposed at the lower surface 100B of the package substrate 100.

In certain embodiments, the first region 102 and the second region 106 may be made of graphene. Graphene refers to a two-dimensional (2D) thin film having a honeycomb structure including a single planar sheet of carbon atoms, which has a structure of a 2D carbon hexagonal lattice sheet formed as carbon atoms are chemically bonded by an sp² hybrid orbital. A thickness of the graphene single layer may be equal to that of a single atom, approximately 0.3 nm. Graphene has a high charge carrier mobility equivalent to approximately 1000 times that of silicon (Si) and high electrical conductivity equivalent to approximately 100 times that of copper (Cu). Also, graphene has excellent thermal conductivity and thermal stability. Graphene may have thermal conductivity equal to or higher than 5000 W/mk and may stably maintain its characteristics even at a temperature of 1000° C. or above. Further, multiple graphene layers are known to have thermal conductivity of approximately 1000 W/mk.

In certain embodiments, thus, the first region 102 and the second region 106 may be used as a path transmitting heat from the light emitting device 120 and also as a path transmitting an electrical signal from the light emitting device 120 to an external device.

In certain embodiments, the insulating region 104 may be made of a polymer resin having high heat resistance to maintain insulation characteristics even in a high temperature process for forming graphene in the first region 102 and the second region 106. The insulating region 104 may be made of, for example, a polyimide resin.

The light emitting device 120 may include a light emitting diode (LED). An LED is a type of semiconductor device, outputting light having a predetermined wavelength by power applied from the outside. A single light emitting device 120 may be provided as illustrated, or a plurality of light emitting devices may be provided. The light emitting device 120 may include a device substrate 121, a first electrode 122, a first conductivity-type semiconductor layer 124, an active layer 125, a second conductivity-type semiconductor layer 126, and a second electrode 128.

In certain embodiments, the device substrate 121 may serve as a support when a process such as a laser lift-off process, or the like, is performed to remove a semiconductor growth substrate. In the present embodiment, the device substrate 121 may be made of a conductive material. The device substrate 121 may serve as an electrode of the light emitting device together with the first electrode 122. The device substrate 121 may be made of a material including any one among gold (Au), nickel (Ni), aluminum (Al), copper (Cu), tungsten (W), silicon (Si), selenium (Se), gallium arsenide (GaAs), e.g., a material doped with aluminum (Al) on silicon (Si). In this case, the device substrate 121 may be formed through a method such as plating, bonding, or the like, as required by the selected material. According to an embodiment, the device substrate 121 may be positioned above the second electrode 128.

In certain embodiments, the first conductivity-type semiconductor layer 124 and the second conductivity-type semiconductor layer 126 may be a p-type semiconductor layer and an n-type semiconductor layer, respectively, but the present disclosure is not limited thereto and, conversely, the first conductivity-type semiconductor layer 124 and the second conductivity-type semiconductor layer 126 may be an n-type semiconductor layer and a p-type semiconductor layer, respectively. The first conductivity-type semiconductor layer 124 and the second conductivity-type semiconductor layer 126 may be nitride semiconductors and may be a material such as GaN, AlGaN, InGaN, or the like, having an empirical formula AlₓIn_{y}Ga_{(1-x-y)}N (here, 0≦x≦1, 0≦y≦1, and 0≦x+y≦1).

In certain embodiments, the active layer 125 may be disposed between the first conductivity-type semiconductor layer 124 and the second conductivity-type semiconductor layer 126, and emits light having a predetermined level of energy according to electron hole recombination. The active layer 125 may have a multiple quantum wells (MQW) structure in which quantum well layers and quantum barrier layers are alternately laminated. For example, an InGaN/GaN structure may be used.

In certain embodiments, the first electrode 122 and the second electrode 128 may be made of a conductive material, e.g., one or more materials such as silver (Ag), aluminum (Al), nickel (Ni), chromium (Cr), or the like, as known in the art. The light emitting device 120 according to the present embodiment may have a vertical structure in which the first electrode 122 and the second electrode 128 are disposed on surfaces opposing one another. In the present disclosure, the first electrode 122 and the second electrode 128 may include contact layers (not shown) made of a semiconductive material. Alternatively, the contact layers may be interposed between the first electrode 122 and the first conductivity-type semiconductor layer 124 and between the second electrode 128 and the second conductivity-type semiconductor layer 126. According to an embodiment, the size of the first electrode 122 and the second electrode 128 may be variously changed.

In certain embodiments, the phosphor layer 130 may include a phosphor emitting light having a different wavelength upon being excited by light emitted from the light emitting device 120. Light emitted from the phosphors and light emitted from the light emitting device 120 may be combined to obtain desired output light such as white light, or the like. The phosphor layer 130 may be made of an oxide-based, silicate-based, nitride-based, and sulfide-based phosphor mixture, or the like.

In certain embodiments, the encapsulator 160 encapsulates the light emitting device 120. As illustrated, a surface of the encapsulator 160 may have a lens structure having a convex or concave shape to adjust an angle of beam spread of light emitted through the upper surface of the encapsulator 160. The encapsulator 160 may be formed to have a predetermined shape above the light emitting device 120, the phosphor layer 130, and the conductive wire 150 and hardened. The encapsulator 160 may be made of a resin having high transparency allowing light generated from the light emitting device 120 to pass therethrough with a minimum level of loss. For example, the encapsulator 160 may be made of an elastic resin, silicon, an epoxy resin, or plastic.

In certain embodiments, the light emitting device 120 is mounted on an upper surface of the package substrate 100, and the first electrode 122 may be bonded to an upper surface of the first region 102 by a bonding layer 110 so as to be electrically connected to the first region 102. The bonding layer 110 may be made of an electrically conductive material. The second electrode 128 of the light emitting device 120 may be electrically connected to the second region 106 of the package substrate 100 by a conductive wire 150.

The first region 102 of the package substrate 100 has a first length L1 in one direction, and the light emitting device 120 has a second length L2 in one direction. In the drawings, the first length L1 and the second length L2 are illustrated as being equal but the first length L1 may be greater or smaller than the second length L2 according to certain embodiments. However, in order to enhance heat dissipation effect of the package substrate 100, the first region 102 may be formed to have a size corresponding to the entire surface of the package substrate 100 on which the first electrode 122 is mounted.

The package substrate 100 has a first thickness T1, and the first thickness T1 may range, for example, from 20 μm to 200 μm. Thus, the package substrate 100 according to an embodiment of the present disclosure may be a thin flexible substrate. The light emitting device 120 may have a second thickness T2, and the second thickness T2 may be similar to the first thickness T1 or smaller.

In the case of the light emitting device package 1000 according to the foregoing embodiment, since it has the package substrate 100 having the first region 102 and the second region 106 made of graphene, the heat dissipation effect can be improved through the graphene. Also, the graphene forming the first region 102 and the second region 106 can serve as electrode pads by themselves, not requiring an extra electrode pad disposed on an upper surface or a lower surface of the package substrate 100. Also, since a thickness of the graphene can be easily adjusted, the thickness of the package substrate 100 can be minimized so as to be easily applied to a flexible display.

FIG. 2 is a cross-sectional view schematically illustrating a light emitting device package according to an another embodiment of the present disclosure. In the following description with reference to the drawings, the same reference numerals denote the same components, so a repeated description will be omitted.

Referring to FIG. 2, a light emitting device package 1000a according to an embodiment of the present disclosure may include the package substrate 100, a light emitting device 120′, a phosphor layer 130′, and the encapsulator 160. The light emitting device package 1000a may include a different type light emitting device 120′ instead of the light emitting device 120 of the light emitting device package 1000 of FIG. 1.

In certain embodiments, the light emitting device 120′ may include a device substrate 121′, a first electrode 122′, a first conductivity-type semiconductor layer 124′, an active layer 125′, a second conductivity-type semiconductor layer 126′, a second electrode 128′, and a via v. The electrode 122′ formed on the device substrate 121′ may be electrically connected to the first conductivity-type semiconductor layer 124′ positioned in an upper side through the via v. The second electrode 128′ may be positioned to be electrically separated from the first electrode 122′ by the interlayer insulating layer 123′ and may be electrically connected to the second conductivity-type semiconductor layer 126′.

The first electrode 122′ may be electrically connected to the first region 102 of the package substrate 100 through the device substrate 121′. The second electrode 128′ may be electrically connected to the second region 106 of the package substrate 100 by a conductive wire 150. A number, a shape, a pitch, a contact area, and the like, of the via v may be adjusted to have low contact resistance with the first electrode 122′. The via v may be made of a material different from that of the first electrode 122′.

In certain embodiments, the interlayer insulating layer 123′ may be made of any material as long as it has electrical insulation properties, and may include a material, e.g., a silicon oxide or a silicon nitride, which absorbs light at a minimum level.

In certain embodiments, in the light emitting device package 1000a, as described above, the via v is used for an electrical connection of the first conductivity-type semiconductor layer 124′, and an electrode is not positioned on an upper surface of the first conductivity-type semiconductor layer 124′. Thus, a quantity of light emitted from an upper surface of the first conductivity-type semiconductor layer can be increased. Meanwhile, the light emitting device package 1000a according to the foregoing embodiment sufficiently guarantees a current dispersion effect by the vias v formed within the first conductivity-type semiconductor layer 124′.

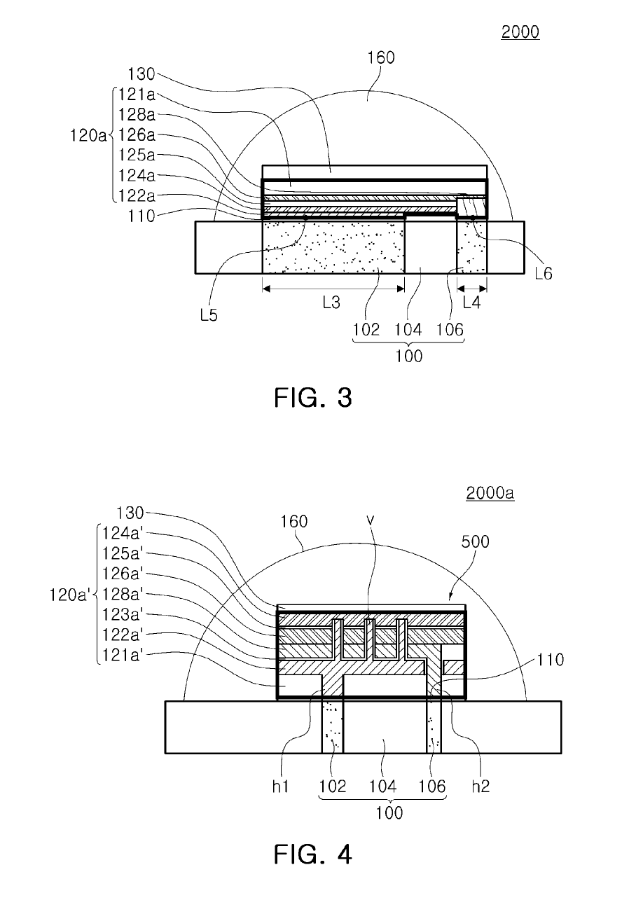

FIG. 3 is a cross-sectional view schematically illustrating a light emitting device package according to an embodiment of the present disclosure. In the following description with reference to the drawings, the same reference numerals denote the same components, so a repeated description will be omitted.

Referring to FIG. 3, a light emitting device package 2000 according to an embodiment of the present disclosure may include the package substrate 100, a light emitting device 120a, the phosphor layer 130, and the encapsulator 160. In the present embodiment, the light emitting device 120a has a horizontal structure and is mounted in the form of a flip chip on the package substrate 100.

In certain embodiments, the light emitting device 120 may include a device substrate 121a, a first electrode 122a, a first conductivity-type semiconductor layer 124a, an active layer 125a, a second conductivity-type semiconductor layer 126a, and a second electrode 128a. The device substrate 121a may be used as a semiconductor growth substrate or serve as a support when a process such as a laser lift-off process, or the like, is performed to remove a semiconductor growth substrate. In the present embodiment, the device substrate 121 may be made of a conductive material or an insulating material. When the device substrate 121a is made of a conductive material, the device substrate 121a may be made of a material including any one among gold (Au), nickel (Ni), aluminum (Al), copper (Cu), tungsten (W), silicon (Si), selenium (Se), gallium arsenide (GaAs), e.g., a material doped with aluminum (Al) on silicon (Si). When the device substrate 121a is made of an insulating material, a material having excellent heat dissipation characteristics or a material having a coefficient of thermal expansion similar to that of a lower material, and the like, may be appropriately selected and used. For example, an aluminum oxide (Al₂O₃), an aluminum nitride (AlN), an undoped silicon, or the like, may be used.

In certain embodiments, the first conductivity-type semiconductor layer 124a and the second conductivity-type semiconductor layer 126a may be a p-type nitride semiconductor and an n-type nitride semiconductor, respectively, and may be a material such as GaN, AlGaN, InGaN, or the like, having an empirical formula AlₓIn_{y}Ga_{(1-x-y)} (here, 0≦x≦1, 0≦y≦1, and 0≦x+y≦1).

The active layer 125a may be disposed between the first conductivity-type semiconductor layer 124a and the second conductivity-type semiconductor layer 126a and have a multiple quantum well (MQW) structure in which quantum well layers and quantum barrier layers are alternately laminated. For example, an InGaN/GaN structure may be used.

The first electrode 122a and the second electrode 128a may be made of a conductive material, e.g., one or more of materials such as silver (Ag), aluminum (Al), nickel (Ni), chromium (Cr). In the light emitting device 120a according to the present embodiment, the first electrode 122a and the second electrodes 128a are disposed in the same side.

In certain embodiments, the light emitting device 120a is mounted on an upper surface of the package substrate 100. The first electrode 122a and the second electrode 128a of the light emitting device 120a are bonded (or joined) to upper surfaces of the first region 102 and the second region 106 of the package substrate 100 so as to be electrically connected to the first region 102 and the second region 106.

In certain embodiments, the first region 102 of the package substrate 100 has a third length L3 in one direction, and the second region 106 thereof has a fourth length L4 smaller than the third length L3. The first electrode 122a of the light emitting device 120a has a fifth length L5 in the one direction, and the second electrode 128a thereof has a sixth length L6. The third length L3 and the fourth length L4 may be equal or similar to the fifth length L5 and the sixth length L6, respectively. The third to sixth lengths L3, L4, L4, and L6 may be variously changed according to a certain embodiment, without being limited to the illustrated relationship. In this case, however, in order to enhance a heat dissipation effect of the package substrate 100, the first region 102 and the second region 106 may be formed to have a size corresponding to the entire surface of the package substrate 100 on which the first electrode 122a and the second electrode 128a are mounted.

FIG. 4 is a cross-sectional view schematically illustrating a light emitting device package according to an embodiment of the present disclosure. In the following description with reference to the drawings, the same reference numerals as those in FIGS. 1 through 3 denote the same components, so a repeated description thereof will be omitted.

Referring to FIG. 4, a light emitting device package 2000a according to an embodiment of the present disclosure may include the package substrate 100, a light emitting device 120a′, the phosphor 130, and the encapsulator 160. The light emitting device package 2000a may include the different type light emitting device 120a′ in the place of the light emitting device 120a of the light emitting device package 2000.

The light emitting device 120a′ may include a device substrate 121a′, a first electrode 122a′, an interlayer insulating layer 123a′, a first conductivity-type semiconductor layer 124a′, an active layer 125a′, a second conductivity-type semiconductor layer 126a′, a second electrode 128a′, and a via v.

The first electrode 122a′ may be formed on the device substrate 121a′ and may be electrically connected to the first conductivity-type semiconductor layer 124a′ positioned in an upper portion thereof through the via v. The second electrode 128a′ is positioned to be electrically separated from the first electrode 122a′ by the interlayer insulating layer 123a′ and may be electrically connected to the second conductivity-type semiconductor layer 126a′.

The first electrode 122a′ has a first hole h1 extending in a direction toward the device substrate 121a′ and electrically connected to the first region 102, and similarly, the second electrode 128a′ has a second hole h2 extending in a direction toward the device substrate 121a′ and electrically connected to the second region 106. The first hole h1 and the second hole h2 may be formed as through holes and variously modified according to a certain embodiment.

In the case of the light emitting device package 2000a according to the present embodiment as described above, the via v is used for an electrical connection of the first conductivity-type semiconductor layer 124a′, and an electrode is not positioned on an upper surface of the first conductivity-type semiconductor layer 124a′. Thus, a quantity of light emitted from the upper surface of the first conductivity-type semiconductor layer 124a′ can be increased. In addition, since the light emitting device package 2000a according to the present embodiment does not use a conductive wire, it is advantageous in terms of reliability, light extraction efficiency, and process convenience.

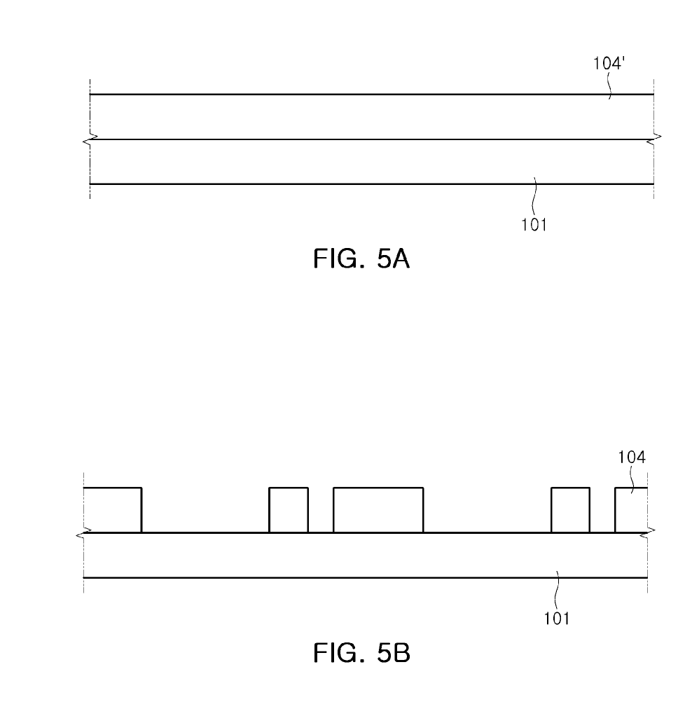

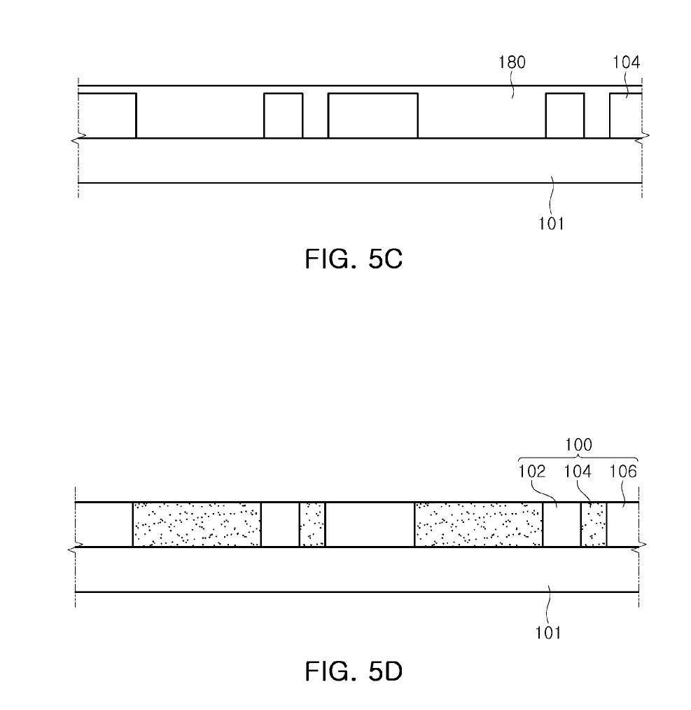

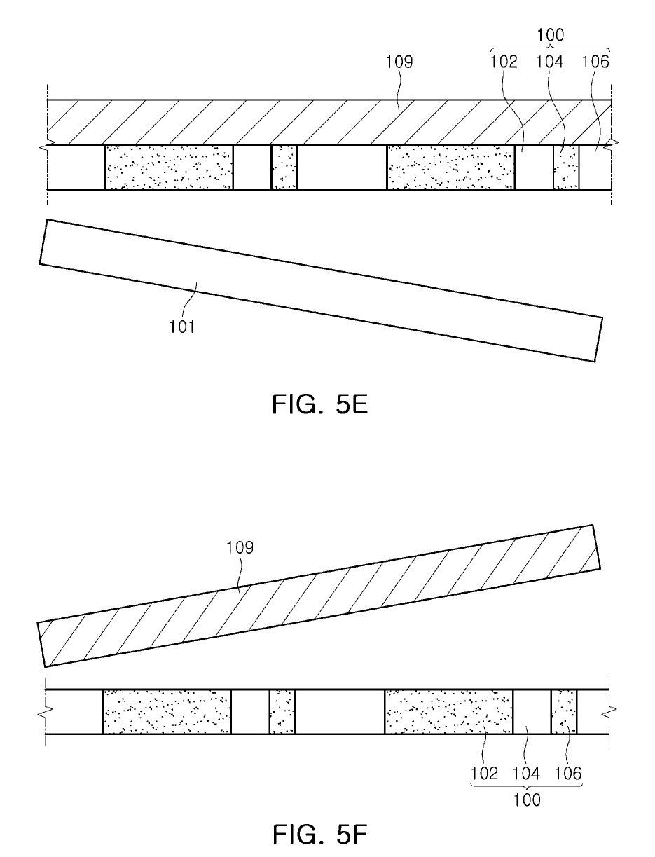

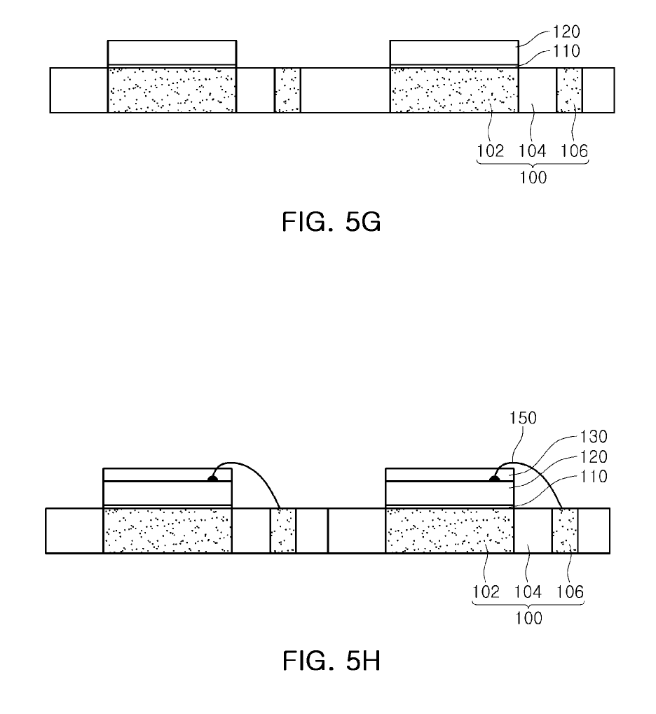

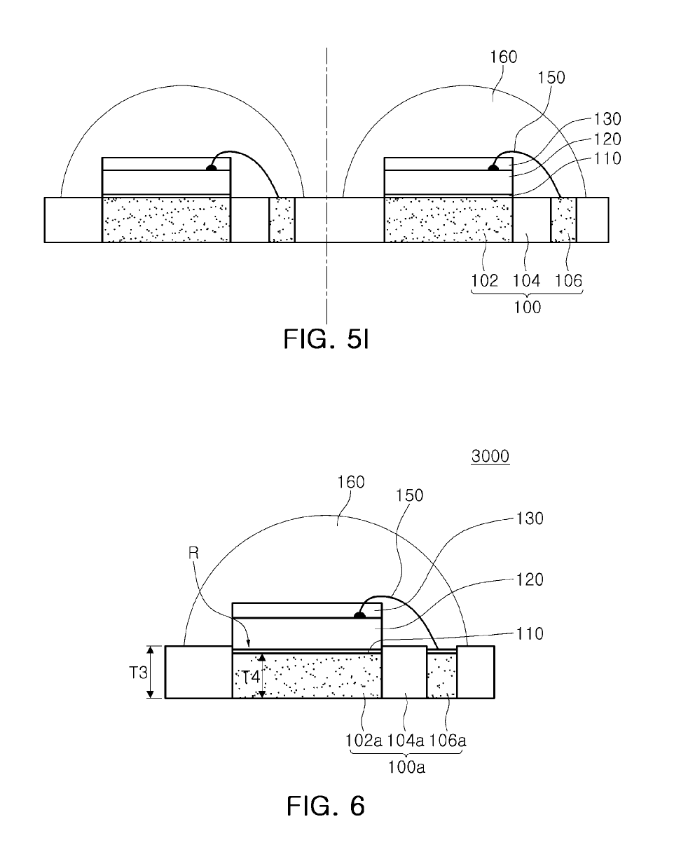

FIGS. 5A through 5I are cross-sectional views illustrating a sequential process of fabricating a light emitting device package according to an embodiment of the present disclosure. FIGS. 5A through 5I will be described based on the light emitting device package of FIG. 1, but the light emitting device packages illustrated in FIGS. 2 through 4 may also be manufactured in a similar manner.

Referring to FIG. 5A, an operation of forming an insulating layer 104′ on a base substrate 101 may be performed in certain embodiments.

The base substrate 101 may include a metal serving as a catalyst for growing graphene in a follow-up process. The base substrate 101 may include, for example, nickel (Ni), cobalt (Co), palladium (Pd), iron (Fe), platinum (Pt), copper (Cu), ruthenium (Ru), iridium (Ir), and rhodium (Rh). For example, the base substrate 101 may be a copper foil.

The insulating layer 104′ may be a thin film made of an insulating material forming the insulating region 104 in FIG. 1. The insulating layer 104′ may be made of a material, such as a polyimide resin, having high temperature stability. The insulating layer 104′ may be formed to have a predetermined thickness on the base substrate 101 through, for example, spin-coating.

Referring to FIG. 5B, a process of patterning the insulating layer 104′ to form an insulating region 104 may be performed. The patterning process may be performed by forming a mask pattern on the insulating layer 104′ and etching the insulating layer 104′ exposed through the mask pattern. The etching process may be performed through a wet etching or a dry etching process, such as reactive ion etching (RIE).

With the insulating region 104 formed, an upper surface of the base substrate 101 may be exposed in regions corresponding to the first region 102 and the second region 106 in FIG. 1.

Referring to FIG. 5C, an operation of forming a carbon source layer 180 for graphene may be performed on the exposed base substrate between the insulating regions 104. The carbon source layer 180 may be made of, for example, any one of polystyrene (PS), polyacrylonitrile (PAN), and polymethylmethacrylate (PMMA). The carbon source layer 180 may be formed through a spin-coating method and. In certain embodiments, the carbon source layer 180 may be formed to have a thickness ranging from tens of nano-meters to hundreds of nano-meters according to a thickness of the package substrate 100 intended to be formed.

Referring to FIG. 5D, an operation of thermally treating the carbon source layer 180 to form graphene on the first region 102 and the second region 106 may be performed. The carbon source layer 180 may be thermally treated, for example, at a temperature of approximately 800° C. or below in a vacuum state under an argon (Ar) and hydrogen (H₂) gas atmosphere. Accordingly, the carbon source layer 180 is decomposed to form graphene. The graphene may be formed as a single layer or as a plurality of layers according to a thickness of the carbon source layer 180. As the first region 102 and the second region 106 are formed, the package substrate 100 may be finally formed.

In the present embodiment, the process of forming graphene from the carbon source layer 180 is illustrated and described, but the present disclosure is not limited thereto.

Various methods for forming graphene have been known. Graphene may be formed through chemical vapor deposition (CVD), molecular beam epitaxy (MBE), a mechanical delamination method for delamination from graphite crystal, or a silicon carbide (SiC) crystal pyrolysis method.

When graphene is formed through CVD and MBE, graphene epitaxy may be grown on a sapphire substrate by using MBE or CVD, and in this case, the epitaxial growth can be easily achieved due to crystallographic compatibility between graphene and the sapphire substrate. Graphene may also be formed at a low temperature equal to or lower than 250° C. by using microwave assisted surface wave plasma CVD (MW-SWP CVD).

An adhesive tape method, a type of mechanical delamination method, is a fine mechanical delamination method. According to this method, adhesive tape is attached to a graphite sample and subsequently detached therefrom to obtain a graphene sheet separated from graphite, from a surface of the adhesive tape.

The silicon carbide (SiC) crystal pyrolysis method uses a principle that, when SiC single crystal is heated, SiC on a surface thereof is decomposed to remove silicon (Si) and remaining carbon forms a graphene sheet. In addition, graphene may be formed by using a deposition process, exfoliation of highly ordered pyrolytic graphite (HOPG), chemical reduction of graphite oxide foil, thermal exfoliation, electrostatic deposition, liquid phase exfoliation of graphite, arc-discharging, a solvothermal method, or the like.

Referring to FIG. 5E, first, an operation of forming a support substrate 109 on the package substrate 100 may be performed. The support substrate 109 may be a substrate supporting the package substrate 100 when the base substrate 101 is removed. Thus, the support substrate 109 may be made of a material that may be removed through wet etching. For example, the support substrate 109 may be formed by depositing an acrylic resin, e.g., PMMA, to have a predetermined thickness through spin-coating. However, a material of the support substrate 109 is not limited to a particular material. The support substrate 109 may be formed in a manner of attaching a molded substrate or may include silicon, glass, ceramic, plastic, or the like.

In certain embodiments, a process of removing the base substrate 101 may be performed. The base substrate 101 may be removed through a chemical process such as etching or may be physically removed through a grinding process. Or, the base substrate 101 may be removed through a laser lift-off process by irradiating a laser to an interface between the base substrate 101 and the package substrate 100. A method for removing the base substrate 101 is not limited to the foregoing method and the base substrate 101 may be removed through various methods.

Referring to FIG. 5F, a process of removing the support substrate 109 may be performed. In certain embodiments, the support substrate 109 may be removed through a wet etching process. For example, when the support substrate 109 is made of PMMA, the support substrate 109 may be decomposed to be removed by a solution such as acetone through a wet etching process.

In this process, the package substrate 100 may be finally formed. The thickness of the package substrate 100 may be 200 μm or less and may be changed according to a thickness of the graphene constituting the first region 102 and the second region 106.

Referring to FIG. 5G, a process of mounting the light emitting device 120 on the package substrate 100 may be performed. Respective light emitting devices 120 may be disposed to correspond to the first regions 102 of the package substrate 100, and first electrodes 122 (Please see FIG. 10) of the light emitting devices 120 may be bonded to the first regions 102 so as to be electrically connected. The light emitting device 120 may be bonded and electrically connected to the first region 102 through a bonding layer 110 provided on the package substrate 100. The bonding layer 110 may be made of an electrically conductive material. The light emitting device 120 and the first region 102 may be bonded through eutectic bonding, paste bonding, or the like.

Referring to FIG. 5H, a process of electrically connecting the light emitting device 120 and the second region 106 may be performed. The second electrode 128 (please see FIG. 1) of the light emitting device 120 may be electrically connected to the second region 106 by the conductive wire 150. A wiring layer (not shown) extending along a lateral surface of the light emitting device 120 may also be used instead of the conductive wire 150. Then the phosphor layer 130 may be formed on the light emitting device 120. The phosphor layer 130 may convert a wavelength of light output from the light emitting device 120 into a wavelength of a desired color. For example, the phosphor layer 130 may convert monochromatic light such as red light or blue light into white light. A resin used to form the phosphor layer 130 may contain at least one or more types of phosphor materials. Also, an ultraviolet ray absorbent that absorbs ultraviolet rays generated from the phosphor layer 130 may be added according to a certain embodiment.

In certain embodiments, the phosphor layer 130 is selectively made of a resin having a high level of transparency. For example, the phosphor layer 130 may be made of an elastic resin.

Referring to FIG. 5I, the encapsulator 160 may be formed on the package substrate 100 to cover the light emitting device 120. The encapsulator 160 may cover the light emitting device 120, the phosphor layer 130, and the conductive wire 150 to protect them against an external environment. The encapsulator 160 may be formed to have a lens shape protruding upwardly on the respective light emitting devices 120.

Thereafter, as indicated by the alternated long and short dashed lines, the package substrate 100 is severed to separate the light emitting devices 120, thus manufacturing the light emitting device package 1000 as illustrated in FIG. 1.

FIG. 6 is a cross-sectional view schematically illustrating a light emitting device package according to an embodiment of the present disclosure.

Referring to FIG. 6, a light emitting device package 3000 according to an embodiment of the present disclosure includes a package substrate 100a, the light emitting device 120, the phosphor layer 130, and the encapsulator 160. In the present embodiment, the package substrate 100a may have a shape in which a height of an upper surface thereof is uneven.

The package substrate 100a may include a first region 102a and a second region 106a as conductive regions, and the first region 102a and the second region 106a may be electrically separated by an insulating region 104a. The first region 102a and the second region 106a may be made of graphene. The insulating region 104a may be made of a polymer resin having a high degree of heat-resistance, for example, a polyimide resin.

The insulating region 104a has a third thickness T3, and the first region 102a and the second region 106a have a fourth thickness T4 smaller than the third thickness T3. Thus, the upper surface of the package substrate 100a may have a recess R formed on the first region 102a and the second region 106a. Thus, the light emitting device 120 may be mounted in the recess R. A depth of the recess R is not limited to that illustrated in the drawing and may be variously modified according to an embodiment. For example, in a modification according to a certain embodiment, at least portions of the first electrode 122 of the light emitting device 120 and the first conductivity-type semiconductor layer 124 (FIG. 1) may be positioned in the recess R.

The light emitting device package 3000 according to an embodiment of the present disclosure may be manufactured by forming the carbon source layer 180 such that a thickness thereof is lower than that of the insulating layer 104 during the process of forming the carbon source layer 180 as described above with reference to FIG. 5C.

In the case of the light emitting device package 3000 according to an embodiment of the present disclosure as described above, since the thickness of the first region 102a and the second region 106a of the package substrate 100a is further reduced, heat from the light emitting device 120 can be more effectively dissipated downwardly of the package substrate 100. Also, since the insulating region 104a is formed to be thick relative to the first region 102a and the second region 106a, overall stability of the package substrate 100a can be obtained.

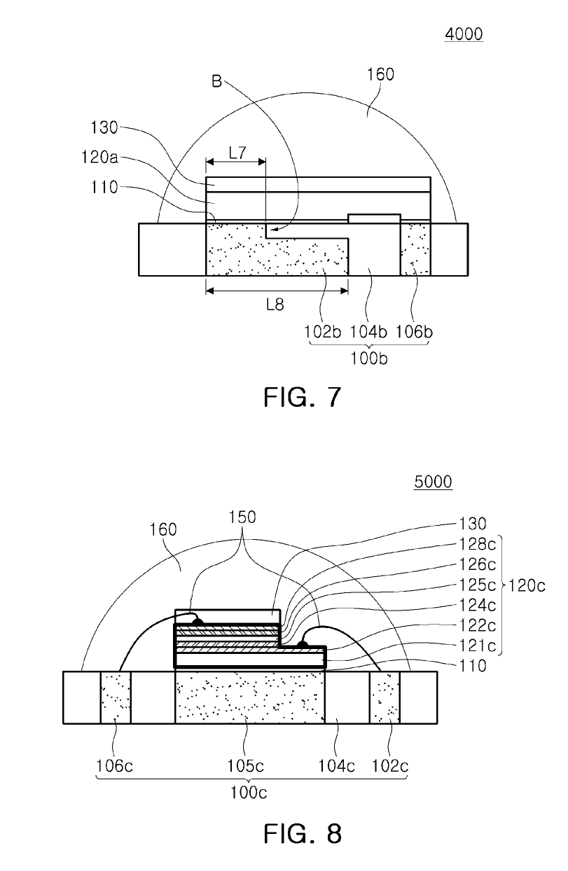

FIG. 7 is a cross-sectional view schematically illustrating a light emitting device package according to an embodiment of the present disclosure.

Referring to FIG. 7, a light emitting device package 4000 according to an embodiment of the present disclosure includes a package substrate 100b, the light emitting device 120a, the phosphor layer 130, and the encapsulator 160. In the present embodiment, the light emitting device 120a has a horizontal structure and the package substrate 100b may include a first region 102b having a bent portion B.

The package substrate 100b may include the first region 102b and a second region 106b as conductive regions, and the first region 102b and the second region 106b may be electrically separated by an insulating region 104b.

The first region 102b has a seventh length L7 in one direction of an upper surface connected to the light emitting device 120a, and has an eighth length L8 greater than the seventh length L7 in a lower surface thereof. Thus, the first region 102b may have the bent portion B in a region in which a length thereof is increased in the one direction. A depth by which the bent portion B is formed is not limited to that illustrated in the drawing. Also, in a certain embodiment, a sloped surface may be formed instead of the bent portion B, whereby the eighth length L8 may be greater than the seventh length L7.

The light emitting device package 4000 according to an embodiment of the present disclosure may be manufactured, for example, by repeatedly performing the process of forming the insulating layer 104′, the carbon source layer 180, and graphene as described above with reference to FIGS. 5A through 5D.

In a certain embodiment, the light emitting device package 4000, although the portion in which the first region 102b of the package substrate 100b is connected to the light emitting device 120a is formed to have an area smaller than the lower surface of the light emitting device 120a, since the lower surface of the first region 102b is formed to be greater than the upper surface thereof, a heat dissipation effect can be improved.

FIG. 8 is a cross-sectional view schematically illustrating a light emitting device package according to an embodiment of the present disclosure.

Referring to FIG. 8, a light emitting device package 5000 according to an embodiment of the present disclosure includes a package substrate 100c, the light emitting device 120c, the phosphor layer 130, and the encapsulator 160. In a certain embodiment, the light emitting device package 5000 include two conductive wires 150. The package substrate 100c may include a first region 102c, a second region 106c, and a third region 105c as conductive regions, and the conductive regions may be electrically separated by insulating regions 104c. The first region, the second region 106c, and the third region 105c may be made of graphene.

The light emitting device 120c may include a device substrate 121c, a first electrode 122c, a first conductivity-type semiconductor layer 124c, an active layer 125c, a second conductivity-type semiconductor layer 126c, and a second electrode 128c. The light emitting device 120c has a horizontal structure in which the first electrode 122c and the second electrode 128c are disposed in a direction opposite to a direction toward the device substrate 121c.

In certain embodiments, the device substrate 121c may be a semiconductor growth substrate and may include an insulating material. The first electrode 122c of the light emitting device 120c may be electrically connected to the first region 120c of the package substrate 100c by the conductive wire 150, and the second electrode 128c may be electrically connected to the second region 106c by the conductive wire 150. Thus, the third region 105c may serve only to dissipate heat generated from the light emitting device 120c, rather than serving to transmit an electrical signal from the light emitting device 120c to an external device. In a modification, the package substrate 100c may not have the third region 105c and may include only the first region 102c, the insulating region 104c, and the second region 106c.

The light emitting device package 5000 according to an embodiment of the present disclosure may be manufactured by patterning the insulating region 104 such that portions of the base substrate 101 corresponding to the first region 102c, the second region 106c, and the third region 105c are exposed during the process of forming the insulating region 104 as described above with reference to FIG. 5B.

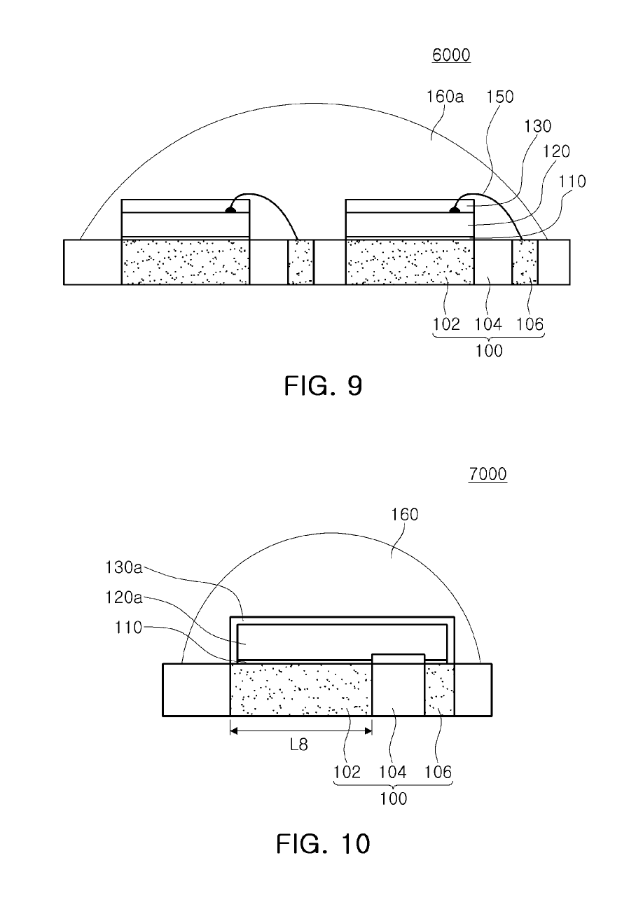

FIG. 9 is a cross-sectional view schematically illustrating a light emitting device package according to an embodiment of the present disclosure.

Referring to FIG. 9, a light emitting device package 6000 according to an embodiment of the present disclosure may include the package substrate 100, the light emitting devices 120, the phosphor layer 130, and an encapsulator 160a. In certain embodiments, the light emitting device package 6000 includes two light emitting devices 120. The light emitting devices 120 may be mounted to be spaced apart by a predetermined distance on an upper surface of the package substrate 100. In certain embodiments, the multi-chip package in which two light emitting devices 120 are mounted is illustrated and described, but three or more light emitting devices 120 may be mounted according to a certain embodiment.

The encapsulator 160a may encapsulate the light emitting devices 120. As illustrated, the encapsulator 160a may be formed to have a dome-like lens structure having a convex upper surface, but the present disclosure is not limited thereto.

The light emitting device package 6000 according to an embodiment of the present disclosure may be manufactured by forming the encapsulator 160a to encapsulate the two light emitting devices 120 during the process of forming the encapsulator 160a as described above with reference to FIG. 5I.

FIG. 10 is a cross-sectional view schematically illustrating a light emitting device package according to an embodiment of the present disclosure.

Referring to FIG. 10, a light emitting device package 7000 according to an embodiment of the present disclosure may include the package substrate 100, the light emitting devices 120a, a phosphor layer 130a, and the encapsulator 160. In a certain embodiment, the phosphor layer 130a may be disposed on a lateral surface of the light emitting device 120a. The phosphor layer 130a may include a phosphor emitting light having a different wavelength upon being excited by light emitted from the light emitting device 120a. Light emitted from the phosphors and light emitted from the light emitting device 120 may be combined to obtain desired output light such as white light, or the like. The phosphor layer 130a may be made of an oxide-based, silicate-based, nitride-based, and sulfide-based phosphor mixture, or the like. In the present embodiment, the phosphor layer 130a may be formed on the lateral surfaces, as well as on the upper surface, of the light emitting device 120a to convert output light emitted from the lateral surfaces.

A light emitting device package 6000 according to a certain embodiment of the present disclosure may be manufactured by forming the phosphor layer 130a to surround the light emitting device 120 during the process of forming the phosphor layer 130 described with reference to FIG. 5H.

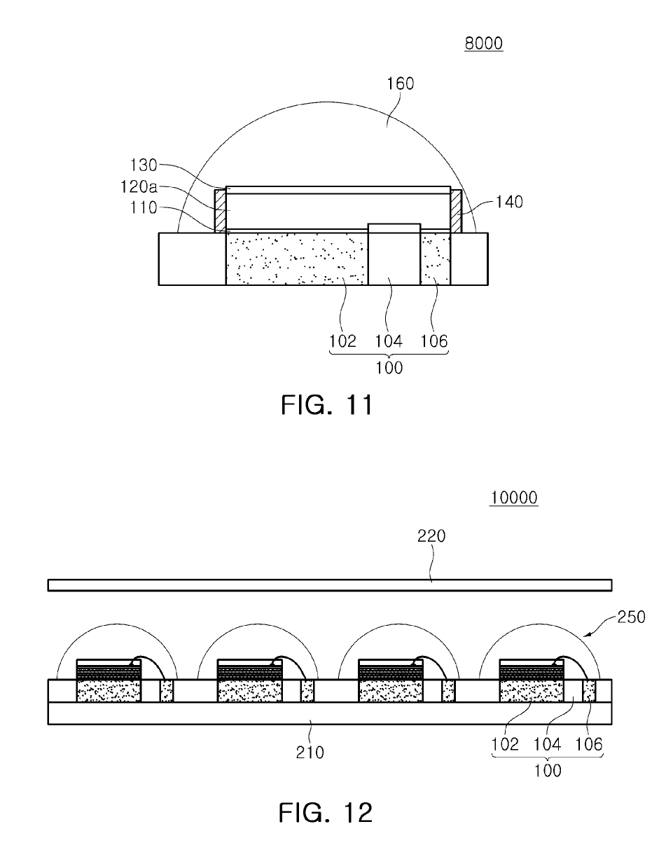

FIG. 11 is a cross-sectional view schematically illustrating a light emitting device package according to an embodiment of the present disclosure. Referring to FIG. 11, a light emitting device package 8000 according to a certain embodiment of the present disclosure may include the package substrate 100, the light emitting devices 120a, the phosphor layer 130, the reflective layer 140, and the encapsulator 160. In the present embodiment, the light emitting device package 8000 may further include the reflective layer 140 disposed on the lateral surfaces of the light emitting device 120a and the phosphor layer 130.

The reflective layer 140 serves to further increase luminous efficiency by reflecting light proceeding toward the lateral surface after being generated from the light emitting device 120a in the direction toward the lens. The reflective layer 140 may include a material having a high level of reflectance. For example, the reflective layer 140 may be made of a material such as white resin obtained by mixing titanium oxide (TiO₂) or aluminum oxide (Al₂O₃) with a polymer resin such as silicon, or may be made of a metal including one or more of aluminum (Al), copper (Cu), and silver (Ag). The reflective layer 140 may be formed to have a circular shape around the light emitting device 120a or may have any other annular shapes such as a quadrangular shape, a polygonal shape, or the like.

The light emitting device package 8000 according to an embodiment of the present disclosure may be manufactured by additionally performing an operation of forming the reflective layer 140 on the lateral surfaces of the light emitting device 120 after the operation of forming the phosphor layer 130 as described above with reference to FIG. 5H.

FIG. 12 is a schematic cross-sectional view illustrating a backlight unit according to an embodiment of the present disclosure. Referring to FIG. 12, a backlight unit 10000 according to the present embodiment may include a plurality of light emitting device packages 250, a cover unit 210 on which a package substrate 100 is mounted, and a diffusion unit 220 disposed above the plurality of light emitting device packages 250 and uniformly spreading light made incident from the plurality of light emitting packages 250.

The plurality of light emitting device packages 250 may be any one of the light emitting device packages 1000, 1000a, 2000, 2000a, 3000, 4000, 5000, 6000, 7000, and 8000 according to a certain embodiment of the present disclosure as described above with reference to FIGS. 1 through 4 and 6 through 11.

The cover unit 210 may be a printed circuit board (PCB) and may include an organic resin material containing epoxy, triazine, silicon, polyimide, or the like, and any other organic resins, a ceramic material such as AlN, Al₂O₃, or the like, or a metal and a metal compound. In detail, the cover unit 210 may be a metal core printed circuit board (MCPCB), a type of metal PCB. The cover unit 210 may further include side walls formed on both sides (not shown) thereof, and the side walls may be in contact with the diffusion unit 220.

Wirings may be formed on an upper surface and a lower surface of the cover unit 210 and electrically connected to the respective light emitting device packages 250. Electrical signals from the plurality of light emitting device packages 250 may be transferred to the cover unit 210 through the first region 102 and the second region 106 of the package substrate 100.

In certain embodiments, the diffusion unit 220 may diffuse light emitted from the plurality of light emitting devices 120 to allow uniform light to be emitted from the entire surface of the diffusion unit 220. The diffusion unit 220 may be made of a transparent plastic material having a high refractive index. For example, the diffusion unit 220 may be made of polycarbonate (PC), polymethylmethacrylate (PMMA), or the like. Also, the diffusion unit 220 may include a diffusion material or beads for diffusing light, and may have depressions and protrusions formed on a surface thereof in order to increase light extraction efficiency. Although not shown in detail, the backlight unit 10000 may further include an optical sheet disposed above or below the diffusion unit 220 in order to diffuse light.

The package substrate 100 constituting the backlight unit 1000 according to a certain embodiment may have a relatively small thickness and may be connected to the cover unit 210 without using an electrode pad, thus allowing a device to be thinner and smaller.

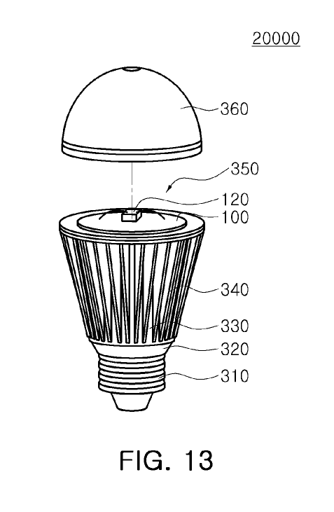

FIG. 13 is a perspective view of a bulb-type lamp as an example of an illumination device according to an embodiment of the present disclosure. To help understanding, FIG. 13 illustrates a state in which a lens unit 360 is not assembled. Referring to FIG. 13, an illumination device 20000 may include an external connection unit 310, a driving unit 330, and a light emitting device package 350. Also, the illumination device 20000 may further include an external structure such as internal and external housings 320 and 340 and a lens unit 360.

In certain embodiments, the driving unit 330 is installed in the internal housing 320 and connected to the external connection unit 310 having a socket structure to receive power from an external power source. The driving unit 330 may serve to convert power into an appropriate current source for driving a light emitting device 120 of the package 350, and transmit the same. For example, the driving unit 330 may be configured as an AC-DC converter, a rectifying circuit component, or the like.

In certain embodiments, the light emitting device 120 may be mounted on the package substrate 100 and installed in the illumination device. Namely, the light emitting device package 350 may be any one the light emitting device packages 1000, 1000a, 2000, 2000a, 3000, 4000, 5000, 6000, 7000, and 8000 according to certain embodiments of the present disclosure as described above with reference to FIGS. 1 through 4 and 6 through 11, except for some components such as the encapsulator 160.

In certain embodiments, the external housing 340 may serve to dissipate heat and may include a heat dissipation plate (not shown) provided on an upper surface thereof and directly connected to the package substrate 100 to improve a heat dissipation effect.

In certain embodiments, the lens unit 360 may be mounted on the light emitting device package 350 and have a convex shape.

In certain embodiments, the light emitting device package 350, such as is used in the lamp of the illumination device 20000, may be variously used in various indoor illumination devices such as a lamp, outdoor illumination devices such as a streetlight, an advertising sign, a beacon light, and the like, and illumination devices for means of transportation such as a head lamp, a taillight, or the like, of automobiles, airplanes, and ships.

As set forth above, according to certain embodiments of the disclosure, a package substrate having excellent heat dissipation characteristics and improved electrical characteristics, and a light emitting device package including the same can be provided. Also, a package substrate that can be fabricated through a simple process and easily controlled in thickness, and a light emitting device package including the same can be provided.

Various advantages and effects of the present disclosure are not limited to the foregoing content and may be easily understood through the process explaining the specific embodiments of the present disclosure.

While the present disclosure has been shown and described in connection with the embodiments, it will be apparent to those skilled in the art that modifications and variations can be made without departing from the spirit and scope of the disclosure as defined by the appended claims.

What is claimed is:

1. A light emitting device package comprising:
a light emitting device including a first electrode and a second electrode; and
a package substrate allowing the light emitting device to be mounted thereon and including a first region and a second region electrically connected to the first electrode and the second electrode, respectively,
wherein at least one of the first region and the second region includes graphene.

2. The light emitting device package of claim 1, wherein the package substrate includes a first surface on which the light emitting device is mounted and a second surface opposing the first surface, and the graphene extends from the first surface to the second surface in the first region and the second region.

3. The light emitting device package of claim 2, wherein at least one of the first region and the second region has an area greater on the second surface than that on the first surface.

4. The light emitting device package of claim 1, wherein at least one of the first region and the second region is positioned below the light emitting device.

5. The light emitting device package of claim 1, wherein the package substrate further includes an insulating region positioned between the first region and the second region and electrically separating the first region and the second region.

6. The light emitting device package of claim 5, wherein the first region and the second region has a first thickness, and the insulating region has a second thickness equal to or greater than the first thickness.

7. The light emitting device package of claim 5, wherein the insulating region is made of a polymer resin.

8. The light emitting device package of claim 1, wherein the first electrode and the second electrode are positioned on the same surface of the light emitting device, and
the light emitting device is mounted on the package substrate such that the first electrode and the second electrode face the first region and the second region, respectively.

9. The light emitting device package of claim 8, wherein the entire surface of the first electrode is connected to the graphene of the first region.

10. The light emitting device package of claim 1, wherein the first electrode and the second electrode are positioned on different surfaces of the light emitting device, and
the first electrode is connected to the first region and the second region is electrically connected to the second region by a conductive wire.

11. The light emitting device package of claim 10, wherein the entire surface of the first electrode is connected to the graphene of the first region.

12. The light emitting device package of claim 1, further comprising:
a phosphor layer provided on the light emitting device; and
an encapsulator encapsulating the light emitting device.

13. The light emitting device package of claim 1, further comprising a reflective layer provided on a lateral surface of the light emitting device.

14. The light emitting device package of claim 1,
wherein a thickness of the package substrate ranges from 20 μm to 200 μm.

15. A light emitting device package substrate comprising:
at least one insulating region; and
a plurality of conductive regions separated by the at least one insulating region and made of graphene,
wherein the plurality of conductive regions extend from at least a portion of an upper surface of the substrate on which a light emitting device is mounted, so as to be exposed to a lower surface of the substrate.

16. A light emitting device package, comprising:
a substrate comprising an insulating region and first and second conductive regions;
a light emitting device overlying at least a portion of the first conductive region;
a first electrode in electrical contact with said light emitting device and said first conductive region; and
a second electrode in electrical contact with said light emitting device and said second conductive region,
wherein the insulating and conductive regions extend from a first surface to a second opposing surface of the substrate,
said first and second conductive regions are spaced apart from each other and said insulating region is located between said first and second conductive regions, and
said first and second conductive regions comprise graphene.

17. The light emitting device package according to claim 16, wherein the insulating region comprises a polymer resin.

18. The light emitting device package according to claim 16, wherein the light emitting device comprises a plurality of layers laminated on the first surface of the substrate and the second electrode is disposed on a laminated layer that is at a furthest distance from the first surface of the substrate.

19. The light emitting device package according to claim 16, wherein the light emitting device comprises a plurality of layers laminated on the first surface of the substrate and the second electrode is disposed on a laminated intermediate layer that is not a layer that is at a furthest distance from the first surface of the substrate.

20. The light emitting device package according to claim 16, wherein the light emitting device overlies the first and second conductive regions and said first and second electrodes are in direct electrical contact with said first and second conductive regions, respectively.
